(19) United States
(12) Patent Application Publication
(10) Pub. No.: US 2025/0170625 A1
(43) Pub. Date: May 29, 2025

(54) CHEMICAL SUPPLY APPARATUS AND CHEMICAL EXCHANGE METHOD

(71) Applicant: SEMES CO., LTD., Cheonan-si (KR)

(72) Inventor: Yong Hoon HONG, Seoul (KR)

(73) Assignee: SEMES CO., LTD., Cheonan-si (KR)

(21) Appl. No.: 18/947,185

(22) Filed: Nov. 14, 2024

(30) Foreign Application Priority Data
Nov. 24, 2023 (KR) 10-2023-0165711

(51) Int. Cl. B08B 9/08; B08B 3/08

(52) U.S. Cl. CPC B08B 9/0804; B08B 3/08

(57) ABSTRACT

Disclosed is a chemical exchange method in a liquid treating device including a first tank, a second tank, and a third tank, the method including: a flushing operation of draining chemicals received in the first tank, the second tank, and the third tank, injecting a flushing chemical into each tank and then circulating the flushing chemical, and then draining the flushing chemical; and a liquid exchange operation of supplying a new chemical to at least one of the first tank, the second tank, and the third tank to perform liquid exchange.

### CROSS-REFERENCE TO RELATED APPLICATIONS

This application claims priority to and the benefit of Korean Patent Application No. 10-2023-0165711 filed in the Korean Intellectual Property Office on Nov. 24, 2023, the entire contents of which are incorporated herein by reference.

### TECHNICAL FIELD

The present invention relates to a chemical supply apparatus and a chemical exchange method.

### BACKGROUND ART

Contaminants, such as particles, organic contaminants, and metal contaminants, remaining on a surface of a substrate greatly affect the characteristics and production yield of semiconductor devices. For this reason, a cleaning process of removing various contaminants adhering to the surface of the substrate is very important in the semiconductor manufacturing process, and a process of cleaning the substrate is performed before and after each unit process of manufacturing a semiconductor. The process for removing these foreign substances includes a cleaning process using deionized water or chemical.

The chemical used in the substrate cleaning process may be recovered for reuse. The chemical recovered from a substrate processing unit is directly supplied to a chemical storage tank or recovered to a separate recovery storage tank and then supplied to a chemical storage tank. The recovered chemical in the chemical storage tank is supplied to the substrate processing unit and reused.

However, as the number of times the chemical is reused increases, the problem of the concentration of the chemical deviating from the standard concentration and the problem of fine particles remaining in the chemical occur. Accordingly, when the life of the chemical is reached or the concentration of the chemical changes, a liquid exchange is performed to discharge all of the remaining chemical and replace the chemical with a new chemical.

However, when the concentration of the new chemical filled in the tank and the remaining chemical remaining in the tank and pipe (circulation line) are mixed, the concentration of the new chemical changes, which causes a change in the process performance.

For example, in the process of etching the TiN film of the substrate, when the chemical is continuously reused, Ti ions dissolve in the chemical. When the chemical with high Ti ions is simply liquid-exchanged, there is a disadvantage of not only defects due to the life time, but also a decrease in the stability of the chemical when the chemical with high Ti ions meets the new chemical and is diluted. (Ti ions are a factor that affects the TiN etch rate by decomposing H₂O₂.)

### SUMMARY OF THE INVENTION

The present invention has been made in an effort to provide a chemical supply apparatus and a chemical exchange method that are capable of preventing concentration fluctuations in a chemical during a process of replacing a chemical whose lifetime has expired with a new chemical.

The present invention has also been made in an effort to provide a chemical supply apparatus and a chemical exchange method that are capable of preventing concentration fluctuations in a chemical during liquid exchange between tanks.

The present invention has also been made in an effort to provide a chemical supply apparatus and a chemical exchange method that are capable of minimizing residual chemicals in a tank and a circulation line connected to the tank during liquid exchange between tanks.

The problem to be solved by the present invention is not limited to the above-mentioned problems, and the problems not mentioned will be clearly understood by those skilled in the art from the descriptions below.

An exemplary embodiment of the present invention provides a chemical exchange method in a liquid treating device including a first tank, a second tank, and a third tank, the method including: a flushing operation of draining chemicals received in the first tank, the second tank, and the third tank, injecting a flushing chemical into each tank and then circulating the flushing chemical, and then draining the flushing chemical; and a liquid exchange operation of supplying a new chemical to at least one of the first tank, the second tank, and the third tank to perform liquid exchange.

Further, the flushing operation may include setting a drain time and a flushing chemical injection and circulation operation of each tank to be different, and when the flushing chemical injected into each tank reaches a life time, draining the flushing chemical.

Further, the chemical used in a processing unit may be recovered and stored in the first tank, the chemical provided from the first tank may be stored in the second tank, and a chemical to be supplied to the processing unit may be provided from the second tank and stored in the third tank.

Further, in the flushing operation, a flushing time of the third tank may be set to be relatively longer than a flushing time of the first tank and a flushing time of the second tank.

Further, in the flushing operation, the amount of flushing chemical injected into the third tank may be set to be relatively larger than the amount of flushing chemical injected into the first tank and the amount of flushing chemical injected into the second tank.

Further, the flushing operation may be repeated several times.

Further, the flushing operation may be carried out before a life time of the chemical is reached.

Further, the flushing operation may include: draining the chemicals of the first tank and the third tank; first injecting the flushing chemical into the third tank, internally circulating the flushing chemical through a circulation line connected to the third tank, and draining the chemical of the second tank; circulating the flushing chemical injected into the third tank through a circulation line for supply to which a supply line of a processing unit is connected, and injecting the flushing chemical into the second tank; injecting the flushing chemical into the first tank, and internally circulating the flushing chemical injected into the second tank through a circulation line; internally circulating the flushing chemical injected into the first tank through a circulation line; and draining the chemicals when a flushing time of each of the first tank, the second tank, and the third tank is reached.

Further, an internal circulation of the flushing chemical in the second tank and an internal circulation of the flushing chemical in the third tank may use the same pump.

Further, in the flushing operation, the time at which the flushing chemical is injected into the first tank may be the same as the time at which the flushing chemical is injected into the second tank.

Further, the flushing chemical may be the same chemical as the new chemical.

Further, the new chemical may be supplied only to the second tank and the third tank, excluding the first tank.

According to another exemplary embodiment of the present invention provides a treatment solution supply apparatus for supplying a chemical to a substrate processing apparatus, the treatment solution supply apparatus including: a first tank in which a chemical used in the substrate processing apparatus is recovered; a second tank for receiving the chemical from the first tank; a third tank which receives the chemical from the second tank and is connected with a main circulation line for supplying the chemical to the substrate processing apparatus; a chemical supply source for supplying the chemical to each of the first tank, the second tank, and the third tank; and a controller for controlling the tanks and the chemical supply source to perform a flushing mode in which the chemicals received in the first tank, the second tank, and the third tank are drained, a flushing chemical is injected into each tank and then circulated, and then the flushing chemical is drained, and a liquid exchange mode in which a new chemical is supplied to at least one of the first tank, the second tank, and the third tank to perform liquid exchange.

Further, the controller may sets a drain time and a flushing chemical injection and circulation operation of each tank to be different, and drain the flushing chemical when the flushing chemical injected into each tank reaches a life time in the flushing mode.

Further, the controller may set a flushing time of the third tank to be relatively longer than flushing times of the first and second tanks, and set the amount of flushing chemical injected into the third tank to be relatively larger than the amounts of flushing chemicals injected into the first and second tanks in the flushing mode, and the flushing chemical injection, circulation operation, and draining of each tank may be repeated at least one time.

Further, the controller may control the tanks and the chemical supply source so that the flushing chemical injection and circulation operation and the draining of the third tank are performed with priority over the first tank and the second tank.

Still another exemplary embodiment of the present invention provides a chemical exchange method in a liquid treating device including a first tank for recovering a chemical used in a processing unit, a second tank for receiving the chemical from the first tank, and a third tank for receiving a chemical to be supplied to the processing unit from the second tank, the chemical exchange method including: a flushing operation of, before a life time of a chemical is reached, draining the chemicals received in the first tank, the second tank, and the third tank, injecting a flushing chemical into each tank and then circulating the flushing chemical, and then draining the flushing chemical; and a liquid exchange operation of supplying a new chemical to at least one of the first tank, the second tank, and the third tank to perform liquid exchange, in which the flushing operation includes setting a drain time and the flushing chemical injection and circulation operation of each tank to be different, and when the flushing chemical injected into each tank reaches the life time, draining the flushing chemical, and the chemical used in the processing unit is recovered and stored in the first tank, the chemical provided from the first tank is stored in the second tank, and the chemical to be supplied to the processing unit is provided from the second tank and stored in the third tank.

Further, in the flushing operation, a flushing time of the third tank may be set to be relatively longer than a flushing time of the first tank and a flushing time of the second tank.

Further, in the flushing operation, the amount of flushing chemical injected into the third tank may be set to be relatively larger than the amount of flushing chemical injected into the first tank and the amount of flushing chemical injected into the second tank.

The flushing operation may include: draining the chemicals of the first tank and the third tank; first injecting the flushing chemical into the third tank, internally circulating the flushing chemical through a circulation line connected to the third tank, and draining the chemical of the second tank; circulating the flushing chemical injected into the third tank through a main circulation line to which a supply line of the processing unit is connected, and injecting the flushing chemical into the second tank; injecting the flushing chemical into the first tank, and internally circulating the flushing chemical injected into the second tank through a circulation line; internally circulating the flushing chemical injected into the first tank through the circulation line; and draining the chemicals when a flushing time of each of the first tank, the second tank, and the third tank is reached, in which the internal circulation of the flushing chemical in the second tank and the internal circulation of the flushing chemical in the third tank may use the same pump, the flushing chemical may be the same chemical as the new chemical, and in the liquid exchange operation, the new chemical may be supplied only to the second tank and the third tank, excluding the first tank.

According to the exemplary embodiment of the present invention, it is possible to secure process stability by preventing fluctuations of the concentration of the chemical during the process of replacing the chemical that has reached its life time with a new drug solution.

According to the exemplary embodiment of the present invention, it is possible to prevent changes in the concentration of the chemical when the tanks are liquid-exchanged.

According to the exemplary embodiment of the present invention, it is possible to minimize the residual chemical in the tanks and the circulation lines connected to the tanks during the liquid exchange of the tanks.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a diagram illustrating a substrate processing apparatus according to an exemplary embodiment of the present invention.

FIG. 2 is a diagram schematically illustrating a liquid treating chamber of FIG. 1 according to the exemplary embodiment.

FIG. 3 is a diagram illustrating a chemical supply apparatus connected to the liquid treating chamber.

FIG. 4 is a flow chart illustrating a treatment solution exchange method in the chemical supply apparatus.

FIG. 5 to FIG. 11 are diagrams sequentially illustrating the treatment solution exchange method.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

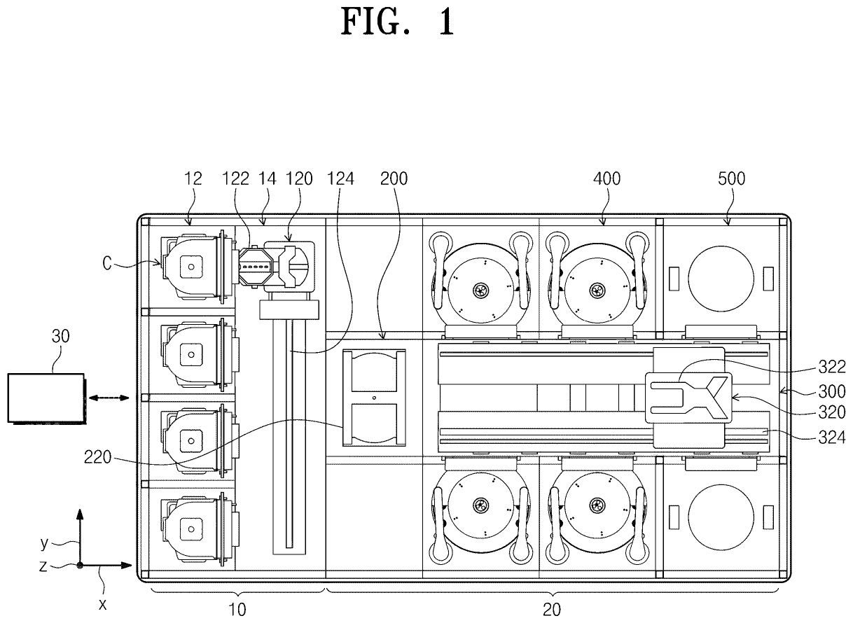

Hereinafter, an exemplary embodiment of the present invention will be described with reference to FIGS. 1 to 11.

FIG. 1 is a diagram illustrating a substrate processing apparatus according to an exemplary embodiment of the present invention.

Referring to FIG. 1, a substrate processing apparatus includes an index module 10, a treating module 20, and a controller 30. When viewed from above, the index module 10 and the processing module 20 are disposed along one direction. Hereinafter, the direction in which the index module 10 and the processing module 20 are arranged is referred to as a first direction X, when viewed from above, a direction perpendicular to the first direction X is referred to as a second direction Y, and a direction perpendicular to both the first direction X and the second direction Y is referred to as a third direction Z.

The index module 10 transfers the substrate W from the container C in which the substrate W is accommodated to the processing module 20, and accommodates the substrate W that has been completely treated in the processing module 20 in the container C. A longitudinal direction of the index module 10 is provided in the second direction Y. The index module 10 includes a load port 12 and an index frame 14. Based on the index frame 14, the load port 12 is located at a side opposite to the treating module 20. The container C in which the substrates W are accommodated is placed in the load port 12. A plurality of load ports 12 may be provided, and the plurality of load ports 12 may be disposed along the second direction Y.

As the container C, an airtight container, such as a Front Open Unified Pod (FOUP), may be used. The container C may be placed on the load port 12 by a transport means (not illustrated), such as an overhead transfer, an overhead conveyor, or an automatic guided vehicle, or an operator.

An index robot 120 is provided to the index frame 14. A guide rail 124 of which a longitudinal direction is provided in the second direction Y is provided in the index frame 14, and the index robot 120 may be provided to be movable on the guide rail 124. The index robot 120 includes a hand 122 on which the substrate W is placed, and the hand 122 may be provided to be movable forward and backward directions, rotatable about the third direction Z and movable along the third direction Z. A plurality of hands 122 are provided to be spaced apart in the vertical direction, and the hands 122 may move forward and backward independently of each other.

The controller 30 may control the substrate processing apparatus. The controller 30 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a treatment recipe, for executing the process in each component according to various data and treatment conditions. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

The processing module 20 includes a buffer unit 200, a transfer chamber 300, a liquid treating chamber 400, and a drying chamber 500. The buffer unit 200 provides a space in which the substrate W loaded into the treating module 20 and the substrate W unloaded from the treating module 20 stay temporarily. The liquid treating chamber 400 performs a liquid treating process of treating the substrate W with a liquid by supplying a liquid onto the substrate W. The drying chamber 500 performs a drying process of removing the liquid residual on the substrate W. The transfer chamber 300 transfers the substrate W between the buffer unit 200, the liquid treating chamber 400, and the drying chamber 500.

A longitudinal direction of the transfer chamber 300 may be provided in the first direction X. The buffer unit 200 may be disposed between the index module 10 and the transfer chamber 300. The liquid treating chamber 400 and the drying chamber 500 may be disposed on the side portion of the transfer chamber 300. The liquid treating chamber 400 and the transfer chamber 300 may be disposed along the second direction Y. The drying chamber 500 and the transfer chamber 300 may be disposed along the second direction Y. The buffer unit 200 may be located at one end of the transfer chamber 300.

According to the example, the liquid treating chambers 400 are disposed on both sides of transfer chamber 300, and the drying chambers 500 are disposed on both sides of the transfer chamber 300, and the liquid treating chambers 400 may be disposed closer to the buffer unit 200 than the drying chambers 500. At one side of the transport chamber 300, the liquid treating chambers 400 may be provided in an arrangement of A×B (each of A and B is 1 or a natural larger than 1) in the first direction X and the third direction Z. Further, at one side of the transfer chamber 300, the drying chambers 500 may be provided in number of C×D (each of C and D is 1 or a natural number larger than 1) in the first direction 92 and the third direction 96. Unlike the above, only the liquid treating chambers 400 may be provided on one side of the transfer chamber 300, and only the drying chambers 500 may be provided on the other side of the transfer chamber 300.

The transfer chamber 300 includes a transfer robot 320. A guide rail 324 of which a longitudinal direction is provided in the first direction X is provided in the transfer chamber 300, and the transfer robot 320 may be provided to be movable on the guide rail 324. The index robot 320 includes a hand 322 on which the substrate W is placed, and the hand 322 may be provided to be movable forward and backward directions, rotatable about the third direction Z and movable along the third direction Z. The plurality of hands 322 is provided while being spaced apart from each other in the vertical direction, and is capable of independently moving forward and backward.

The buffer unit 200 includes a plurality of buffers 220 on which the substrate W is placed. The buffers 220 may be disposed to be spaced apart from each other along the third direction Z. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

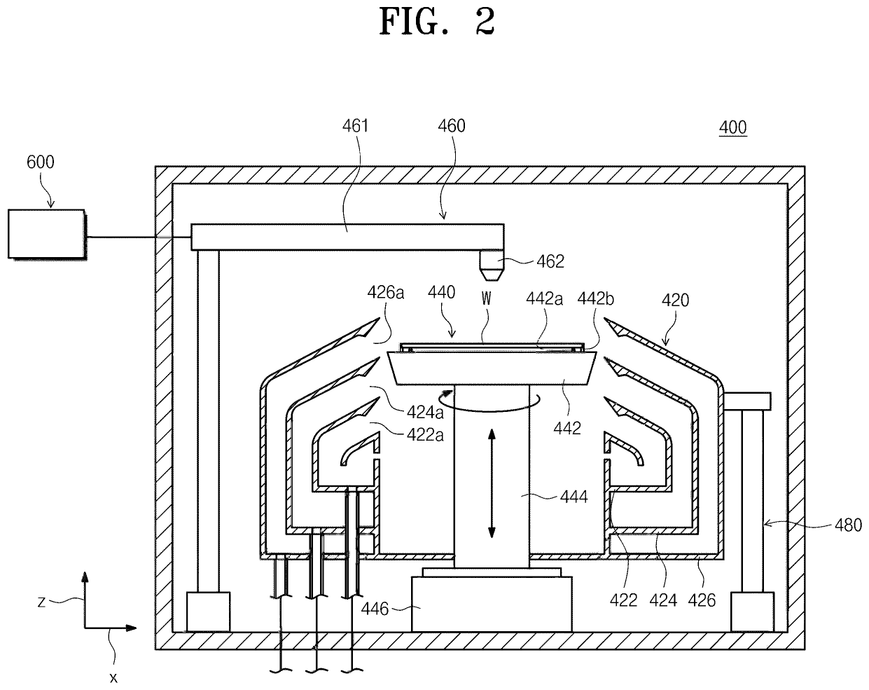

FIG. 2 is a diagram schematically illustrating the liquid treating chamber of FIG. 1 according to an exemplary embodiment.

Referring to FIG. 2, the liquid treating chamber 400 includes a housing 410, a cup 420, a support unit 440, a liquid spraying unit 460, and a lifting unit 480.

The housing 410 may have an interior space where the substrate W is processed. The housing 410 may have a generally hexahedral shape. For example, the housing 410 may have a cuboidal shape. Additionally, the housing 410 may have an opening (not illustrated) through which the substrate W is loaded or unloaded. Additionally, the housing 410 may be equipped with a door (not illustrated) that selectively opens and closes the opening.

The cup 420 may have a barrel shape with an open top. The cup 420 has a processing space, and the substrate W may be liquid-treated within the processing space. The support unit 440 supports the substrate W in the processing space. The liquid spraying unit 460 discharges the treatment liquid onto the substrate W supported by the support unit 440. The treatment solution may be provided in a plurality of types and may be supplied sequentially onto the substrate W. The lifting unit 480 adjusts a relative height between the cup 420 and the support unit 440.

According to the example, the cup 420 includes a plurality of recovery containers 422, 424, and 426. Each of the recovery containers 422, 424, and 426 has a recovery space of recovering the liquid used for the treating of the substrate. Each of the recovery containers 422, 424, and 426 is provided in a ring shape surrounding the support unit 440. As the liquid treating process proceeds, the treatment solution scattered by the rotation of the substrate W enters the recovery space through inlets 422a, 424a, and 426a of the respective recovery containers 422, 424, and 426. According to the example, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be located above a first inlet 422a, which introduces the liquid into the first recovery container 422, and a third inlet 426a, which introduces the liquid into the third recovery container 426, may be located above the second inlet 424a.

The support unit 440 includes a support plate 442 and a driving shaft 444. An upper surface of the support plate 442 may be provided in a generally circular shape, and may have a diameter larger than a diameter of the substrate W. In the center portion of the support plate 442, a support pin 442a is provided to support the rear surface of the substrate W, and the support pin 442a is provided with its upper end protruding from the support plate 442 so that the substrate W is spaced apart from the support plate 442 by a certain distance. A chuck pin 442b is provided to an edge of the support plate 442. The chuck pin 442b is provided to protrude upward from the support plate 442, and supports the lateral portion of the substrate W so that the substrate W is not separated from the support unit 440 when the substrate W is rotated. The drive shaft 444 is driven by a driver 446, is connected to the center of the bottom surface of the substrate W, and rotates the support plate 442 with respect to the central axis thereof.

In one example, the liquid spraying unit 460 may include a nozzle 462. The nozzle 462 may discharge the treatment solution onto the substrate W. The treatment solution may be a chemical, rinse solution, or organic solvent. The chemical may be a chemical having the nature of strong acid or strong base. In addition, the liquid spraying unit 460 can include a plurality of nozzles 462, and each of the nozzles 462 may discharge a different type of treatment liquid. For example, one of the nozzles 462 may discharge a chemical, another of the nozzles 462 may discharge a rinse solution, and another of the nozzles 462 may discharge an organic solvent. The liquid spraying unit 460 receives the treatment liquid (chemical) from the chemical supply device 600.

The present invention may be applied to a wet etching process or a cleaning process for removing a film on the surface of the substrate, and various treatment solutions may be used in these processes. The treatment solution that may be used in the present invention may include at least one or more substances selected from hydrofluoric acid (HF), sulfuric acid (H₃SO₄), hydrogen peroxide (H₂O₂), nitric acid (HNO₃), phosphoric acid (H₃PO₄), ozone water, SC-1 solution (a mixture of ammonium hydroxide (NH₄OH), hydrogen peroxide (H₂O₂), and water (H₂O)) used in the substrate processing process, and in addition, the treatment solution may include treatment solutions of various substances that may be used in the substrate processing process.

The lifting unit 480 moves the cup 420 in the up and down direction. By the up and down movement of the cup 420, a relative height between the cup 420 and the substrate W is changed. Accordingly, since the recovery containers 422, 424, and 426 for recovering the treatment solution are changed according to the type of the liquid supplied to the substrate W, the liquids may be separated and collected. Unlike the description, the cup 420 may be fixedly installed, and the lifting unit 480 may move the support unit 440 in the vertical direction.

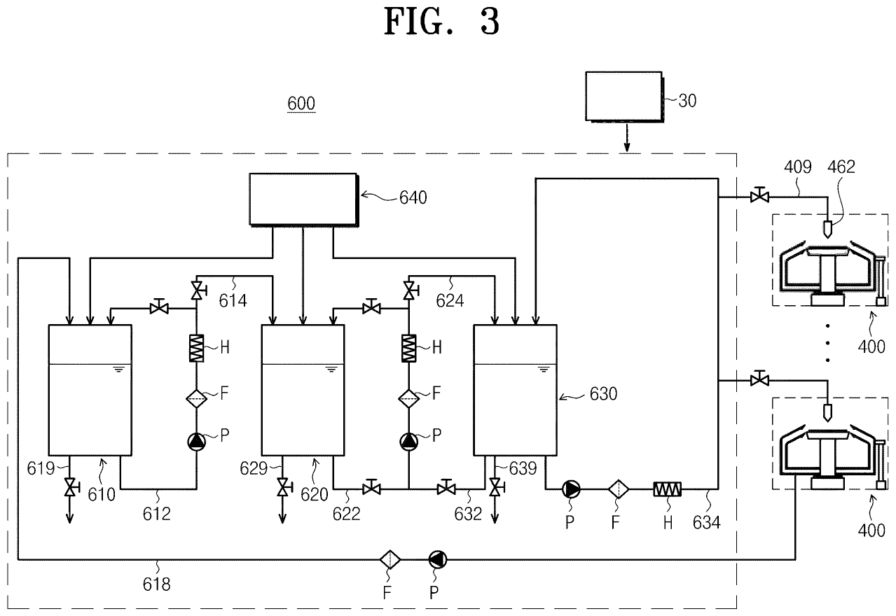

FIG. 3 is a diagram illustrating a chemical supply device connected to the liquid treating chamber.

Referring to FIG. 3, the chemical supply device 600 supplies a chemical used for processing the substrate to the liquid treating chamber 400. In FIG. 3, the chemical supply device 600 may be provided to supply the chemical to a plurality of liquid treating chambers 400. In the liquid treating chamber 400, a process of etching a TiN film of a substrate may be performed. When the chemical is continuously reused in the process of etching the TiN film, the concentration of Ti ions in the chemical increases. When the chemical with a high Ti ion concentration is mixed with a new chemical, the stability of the chemical may deteriorate. Therefore, a flushing process for removing the chemical remaining in each tank and the circulation line of the chemical supply device before supplying a new chemical is very important.

The chemical supply device 600 may include a first tank 610, a second tank 620, a third tank 630, a chemical supply source 640, and a controller 30. The controller 30 may control the first tank 610, the second tank 620, the third tank 630, and the chemical supply source 640.

The first tank 610 is a recycle tank that receives and regenerates the chemical used in the liquid treating chamber 400, the second tank 620 is a sub-tank that performs fine temperature control of the chemical received from the first tank 620, and the third tank 630 is a main tank of the chemical supply device that receives the chemical from the second tank 620 and supplies the chemical to the liquid treating chamber 400.

In the first tank 610, a recovery line 618 is connected to the liquid treating chamber 400. The chemical used in the liquid treating chamber 400 is recovered to the first tank 610 through the recovery line 618. A filter F and a pump P may be installed on the recovery line 618.

The first tank 610 may be replenished with a new chemical so that the chemical recovered through the recovery line 618 may be reused, thereby allowing chemical concentration correction. The new chemical for chemical concentration correction may be supplied through the chemical supply source 640.

The first tank 610 may include a first circulation line 612 and a reuse supply line 614. The first circulation line 612 circulates the chemical stored in the first tank 610. The pump P, the filter F, and a heater H may be installed on the first circulation line 612. The chemical of which the regeneration process is completed in the first tank 610 is supplied to the second tank 620 through a reuse supply line 816. The first tank 610 is provided with a first drain line 619 at the bottom.

The second tank 620 stores the chemical supplied from the first tank 610. The second tank performs a fine temperature correction of the chemical. The second tank 620 may include a second circulation line 622 and a first supply line 624. The second circulation line 622 circulates the chemical stored in the second tank 620. The pump P, the filter F, and the heater H may be installed on the second circulation line 622. The chemical for which temperature correction is completed in the second tank 620 is provided to the third tank 630 through the first supply line 624. The second tank 620 is provided with a second drain line 629 at the bottom.

The third tank 630 stores the chemical supplied from the second tank 620. The third tank 630 may include a third circulation line 632 and a circulation line for supply 634. The third circulation line 632 circulates the chemical stored in the third tank 620. The third circulation line 632 is connected to the second circulation line and may use the pump P, the filter F, and the heater H installed in the second circulation line 622. The pump P, the filter F, and the heater H installed in the second circulation line may be used to circulate the chemical of the third tank 630 internally. The third circulation line 632 may include a portion of the second circulation line 622 in which the pump P, the filter F, and the heater H are installed, and the first supply line 624. The third tank 630 is provided with a third drain line 639 at the bottom. The pump P, the filter F, and the heater H may be installed in the circulation line for supply 634. The supply line 409 of the liquid treating chamber 400 is connected to the circulation line for supply 634. The supply line 409 may be connected to the nozzle 462 of the liquid spraying unit 460 illustrated in FIG. 2.

The valves installed in the first tank 610, the second tank 620, and the third tank 630 may be controlled by the controller 30.

The treatment solution supply source 640 may supply flushing chemicals for flushing the first tank 610, the second tank 620, and the third tank 630 in the flushing mode. The flushing chemical may be the same chemical as the chemical used in the process. After the flushing mode is completed, the chemical supply source 640 may supply a new chemical to the second tank 620 and the third tank 630, excluding the first tank 610.

The controller 30 may control the tanks 610, 620, and 630 and the chemical supply source 640 to perform a flushing mode in which the chemical (existing chemical) received in the first tank 610, the second tank 620, and the third tank 630 is drained, a flushing chemical is injected into each of the tank 610, 620, and 630 and circulated, and then the flushing chemical is drained, and a liquid exchange mode in which a new chemical is supplied to the second tank 620 and the third tank 630 to perform liquid exchange.

The controller 30 may set the drain time and the flushing chemical injection and circulation operation of each tank 610, 620, and 630 differently in the flushing mode. In addition, the controller 30 may control the valves installed in each drain line 629 to drain the flushing chemical when the flushing chemical injected into each tank 610, 620, and 630 reaches its life time.

The controller 30 may set the flushing time of the third tank 630 to be relatively longer than the flushing times of the first and second tanks 610 and 620 in the flushing mode, and may set the flushing chemical injected into the third tank 630 to be relatively more than the flushing chemical injected into the first and second tanks 610 and 620. It is desirable that the flushing mode, which consists of the flushing chemical injection, circulation operation, and draining of each tank 610, 620, and 630 is repeated at least once.

The controller 30 may control the tanks 610, 620, and 630 and the treatment solution supply source 640 so that the flushing chemical injection and circulation operation and drainage in the third tank 630 are performed with priority over the first tank 610 and the second tank 620.

Since the third tank 630 has a relatively longer circulation line than the first and second tanks 610 and 620, the amount of chemical remaining in the circulation line during the liquid exchange is also greater than the chemicals of the first and second tanks 610 and 620. Therefore, the chemical supply device 600 performs the flushing mode of the third tank 630 with priority and injects a relatively large amount of flushing chemical so that rapid flushing is performed, thereby enabling rapid liquid exchange and enabling high-quality chemical supply immediately after flushing.

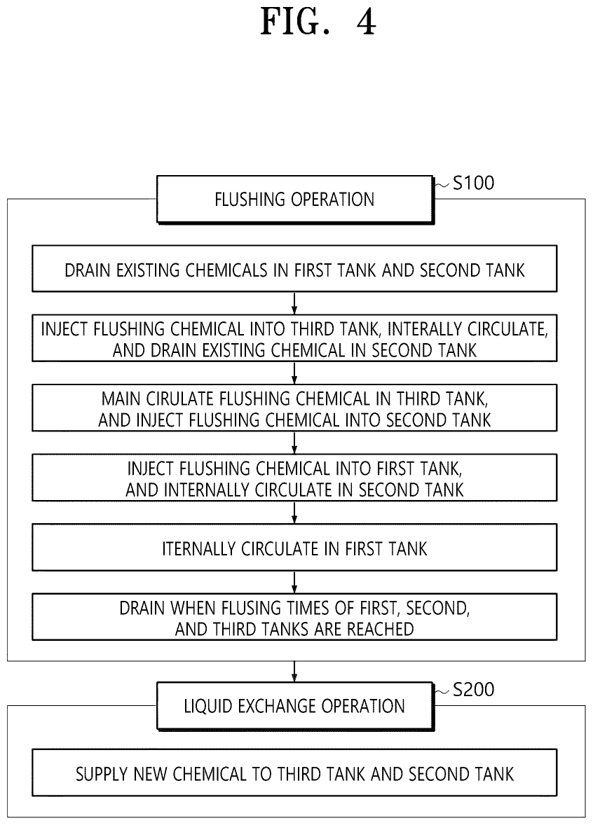

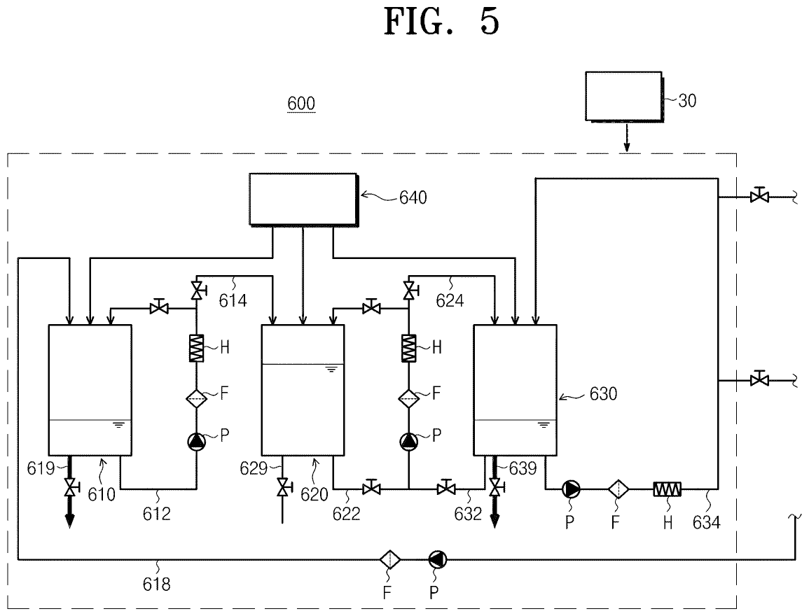

FIG. 4 is a flow chart illustrating a treatment solution exchange method in the chemical supply apparatus, and FIG. 5 to FIG. 11 are diagrams sequentially illustrating the treatment solution exchange method.

Referring to FIGS. 4 to 11, the treatment solution exchange method may include a flushing operation S100 and a liquid exchange operation S200.

The treatment solution exchange is performed before the life time of the chemical of the liquid supply device is reached. For example, when the life time of the chemical is 24 hours, the chemical exchange may be performed when 1 hour remains in the life time of the chemical. The flushing chemical supplied to each tank in the flushing operation uses the same chemical as the chemical used in the process. Therefore, when a new chemical is supplied to each tank after flushing, the phenomenon of a concentration fluctuation of the chemical may be prevented.

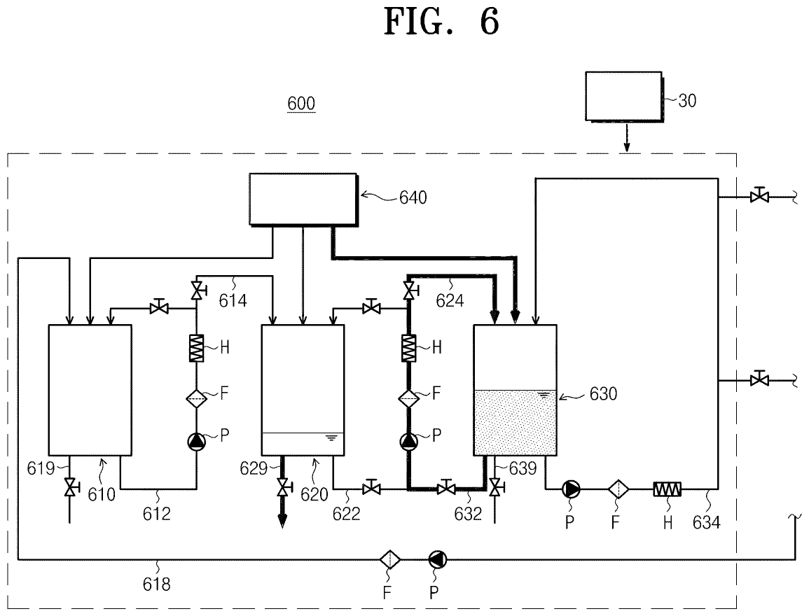

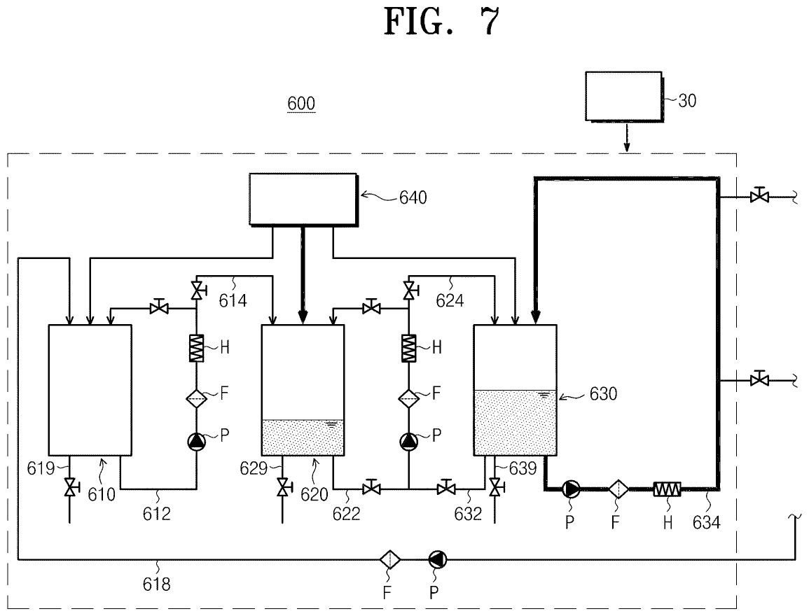

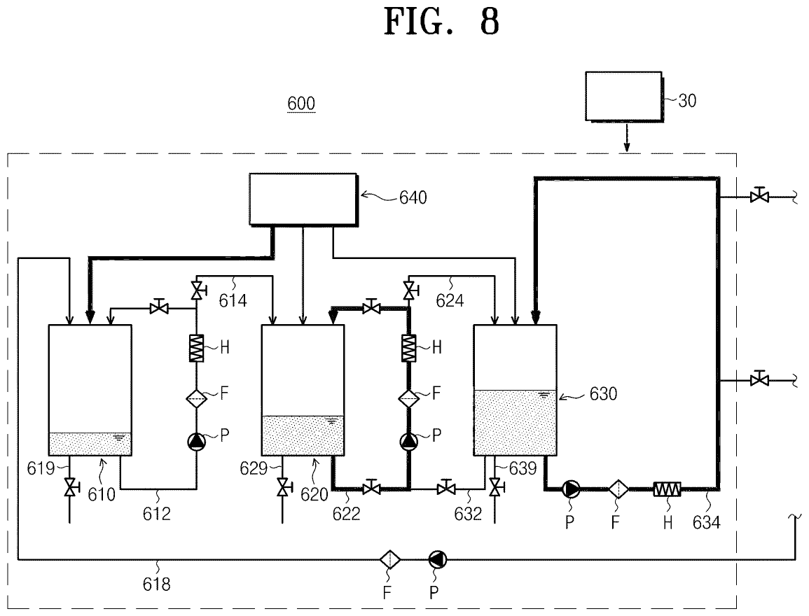

The flushing operation S100 is a process of draining the chemical received in the first tank 610, the second tank 620, and the third tank 630, injecting the flushing chemical into each tank, circulating the flushing chemical, and then draining the flushing chemical. Specifically, firstly, the chemicals in the first tank 610 and the third tank 630 are drained (see FIG. 5). When the chemical draining of the first tank 610 and the third tank 630 is completed, the flushing chemical is first injected into the third tank 630 and the flushing chemical is circulated internally through the third circulation line 632 connected to the third tank 630. In this case, the chemical in the second tank 620 is drained (see FIG. 6). When the chemical draining of the second tank 620 is completed, the flushing chemical injected into the third tank 630 is circulated through the circulation line for supply 634 (main circulation). Then, the flushing chemical is injected into the emptied second tank 620 (see FIG. 7). When the flushing chemical is completely injected to the second tank 620, the flushing chemical is injected to the first tank 610, and the flushing chemical in the second tank 620 is circulated internally through the second circulation line 622 (internal circulation) (see FIG. 8). For example, the time at which the flushing chemical is injected into the first tank 610 may be the same as the time at which the flushing chemical is injected into the second tank 620. However, since the supply capacity of the chemical supply source 640 is limited, it is preferable that the supply of the flushing chemical is sequentially performed for each tank.

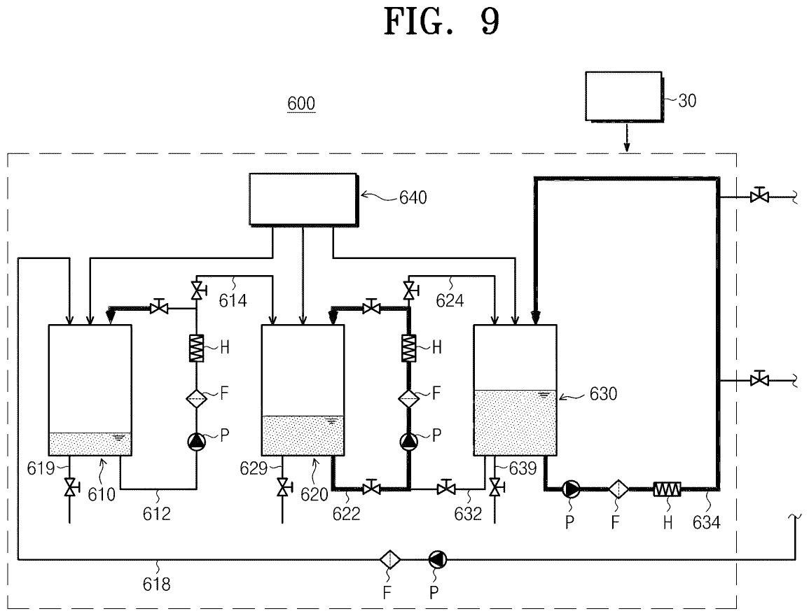

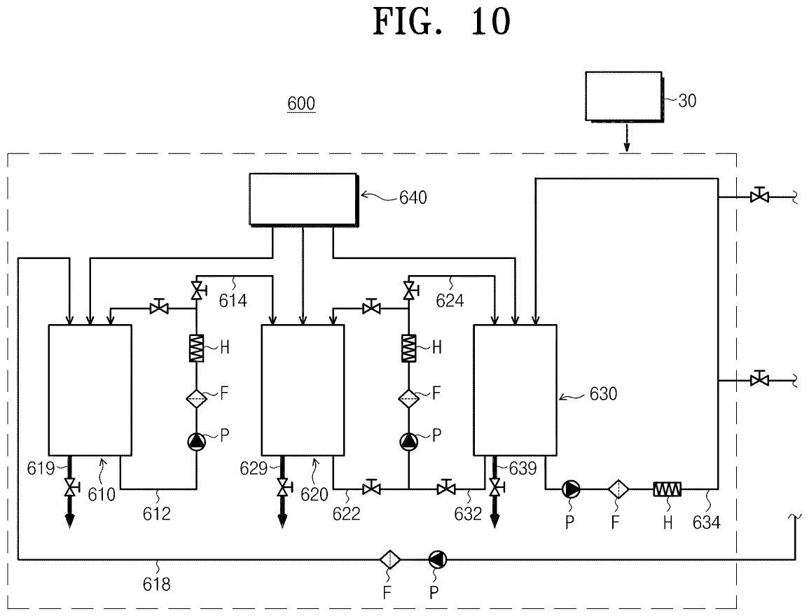

When the flushing chemical injection into the first tank 610 is completed, the flushing chemical of the first tank 610 is internally circulated to the first circulation line 612 (internal circulation) (see FIG. 9). When the flushing time of each of the first tank 610, the second tank 620, and the third tank 630 is reached, the flushing chemical is drained from each tank (see FIG. 10).

In the flushing operation, the flushing time of the third tank 630 is set to be relatively longer than the flushing times of the first and second tanks 610 and 620. For example, the flushing time of the third tank 630 may be set to be 10 minutes, the flushing time of the second tank 620 may be set to be 7 minutes, and the flushing time of the first tank 610 may be set to be 5 minutes. In addition, in the flushing operation, the amount of flushing chemical injected into the third tank 630 may be set to be relatively larger than the amounts of flushing chemicals injected into the first and second tanks 610 and 620. For example, when the storage capacity of the first, second, and third tanks is assumed to be 70 L, the flushing chemical injected into the third tank 630 may be set to 20 L, the flushing chemical injected into the second tank 620 may be set to 10 L, and the flushing chemical injected into the first tank 610 may be set to 7 L. That is, since the third tank 630 includes a relatively longer circulation line than the first and second tanks 610 and 620), the amount of flushing chemical injected and the flushing time are allocated to be relatively long, and the injection of the flushing chemical is also allocated with the highest priority.

Meanwhile, the flushing operation may be repeated 2 to 5 times to remove the residual chemical in the circulation line as much as possible. In particular, the number of flushing operations may be set differently for each tank. For example, the number of flushing operations of the third tank 630 may be set to 4 times, the number of flushing operations of the second tank 620 may be set to 3 times, and the number of flushing operations of the first tank 610 may be set to 2 times. As described above, the process margin may be secured by removing the residual chemical in the circulation line of each tank, and a fresh chemical may be prepared through the dilution discharge of Ti in the circulation line. The heater installed in each circulation line does not operate during the flushing operation.

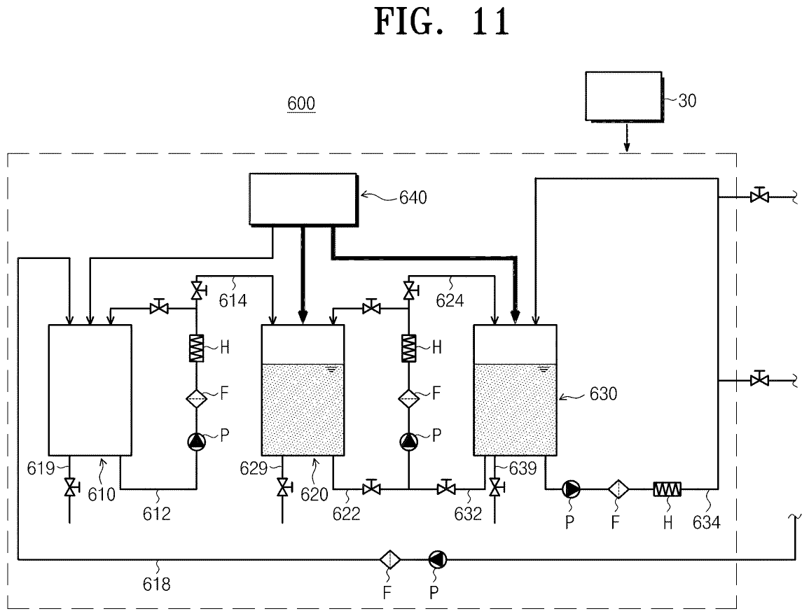

The liquid exchange operation S200 supplies a new chemical to the second tank 620 and the third tank 630, excluding the first tank 610, after the flushing operation is completed (see FIG. 11). The new chemical is supplied from the chemical supply source 640. When the new chemical is supplied to the third tank 630, internal circulation is performed through the third circulation line 632 (heater operation), and when the supply of the chemical to the third tank 630 is completed, the new chemical is circulated through the circulation line for supply 634 (main circulation). When the flushing operation of the second tank 620 is completed, a new chemical is also supplied to the second tank 620, and when the supply of the new chemical to the second tank 620 is completed, internal circulation is performed through the second circulation line 622 (heater operation).

As described above, the treatment solution exchange method in the chemical supply device sets the drain time and the flushing chemical injection and circulation operation differently for each tank, and when the flushing chemical injected into each tank reaches its life time, the flushing chemical is drained and then replaced with a new chemical.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. A chemical exchange method in a liquid treating device including a first tank, a second tank, and a third tank, the method comprising:
a flushing operation of draining chemicals received in the first tank, the second tank, and the third tank, injecting a flushing chemical into each tank and then circulating the flushing chemical, and then draining the flushing chemical; and
a liquid exchange operation of supplying a new chemical to at least one of the first tank, the second tank, and the third tank to perform liquid exchange.

2. The chemical exchange method of claim 1, wherein the flushing operation includes setting a drain time and a flushing chemical injection and circulation operation of each tank to be different, and when the flushing chemical injected into each tank reaches a life time, draining the flushing chemical.

3. The chemical exchange method of claim 1, wherein the chemical used in a processing unit is recovered and stored in the first tank, the chemical provided from the first tank is stored in the second tank, and a chemical to be supplied to the processing unit is provided from the second tank and stored in the third tank.

4. The chemical exchange method of claim 1, wherein in the flushing operation, a flushing time of the third tank is set to be relatively longer than a flushing time of the first tank and a flushing time of the second tank.

5. The chemical exchange method of claim 1, wherein in the flushing operation, the amount of flushing chemical injected into the third tank is set to be relatively larger than the amount of flushing chemical injected into the first tank and the amount of flushing chemical injected into the second tank.

6. The chemical exchange method of claim 1, wherein the flushing operation is repeated several times.

7. The chemical exchange method of claim 1, wherein the flushing operation is carried out before a life time of the chemical is reached.

8. The chemical exchange method of claim 1, wherein the flushing operation includes:
draining the chemicals of the first tank and the third tank;
first injecting the flushing chemical into the third tank, internally circulating the flushing chemical through a circulation line connected to the third tank, and draining the chemical of the second tank;
circulating the flushing chemical injected into the third tank through a circulation line for supply to which a supply line of a processing unit is connected, and injecting the flushing chemical into the second tank;
injecting the flushing chemical into the first tank, and internally circulating the flushing chemical injected into the second tank through a circulation line;
internally circulating the flushing chemical injected into the first tank through a circulation line; and
draining the chemicals when a flushing time of each of the first tank, the second tank, and the third tank is reached.

9. The chemical exchange method of claim 8, wherein an internal circulation of the flushing chemical in the second tank and an internal circulation of the flushing chemical in the third tank use the same pump.

10. The chemical exchange method of claim 8, wherein in the flushing operation, the time at which the flushing chemical is injected into the first tank is the same as the time at which the flushing chemical is injected into the second tank.

11. The chemical exchange method of claim 1, wherein the flushing chemical is the same chemical as the new chemical.

12. The chemical exchange method of claim 1, wherein the new chemical is supplied only to the second tank and the third tank, excluding the first tank.

13.-16. (canceled)

17. A chemical exchange method in a liquid treating device including a first tank for recovering a chemical used in a processing unit, a second tank for receiving the chemical from the first tank, and a third tank for receiving a chemical to be supplied to the processing unit from the second tank, the chemical exchange method comprising:
a flushing operation of, before a life time of a chemical is reached, draining the chemicals received in the first tank, the second tank, and the third tank, injecting a flushing chemical into each tank and then circulating the flushing chemical, and then draining the flushing chemical; and
a liquid exchange operation of supplying a new chemical to at least one of the first tank, the second tank, and the third tank to perform liquid exchange,
wherein the flushing operation includes setting a drain time and the flushing chemical injection and circulation operation of each tank to be different, and when the flushing chemical injected into each tank reaches the life time, draining the flushing chemical, and
the chemical used in the processing unit is recovered and stored in the first tank, the chemical provided from the first tank is stored in the second tank, and the chemical to be supplied to the processing unit is provided from the second tank and stored in the third tank.

18. The chemical exchange method of claim 17, wherein in the flushing operation, a flushing time of the third tank is set to be relatively longer than flushing times of the first and second tanks.

19. The chemical exchange method of claim 17, wherein in the flushing operation, the amount of flushing chemical injected into the third tank is set to be relatively larger than the amount of flushing chemical injected into the first tank and the amount of flushing chemical injected into the second tank.

20. The chemical exchange method of claim 17, wherein the flushing operation includes:
draining the chemicals of the first tank and the third tank;
first injecting the flushing chemical into the third tank, internally circulating the flushing chemical through a circulation line connected to the third tank, and draining the chemical of the second tank;
circulating the flushing chemical injected into the third tank through a main circulation line to which a supply line of the processing unit is connected, and injecting the flushing chemical into the second tank;
injecting the flushing chemical into the first tank, and internally circulating the flushing chemical injected into the second tank through a circulation line;
internally circulating the flushing chemical injected into the first tank through the circulation line; and
draining the chemicals when a flushing time of each of the first tank, the second tank, and the third tank is reached,
the internal circulation of the flushing chemical in the second tank and the internal circulation of the flushing chemical in the third tank use the same pump,
the flushing chemical is the same chemical as the new chemical, and
in the liquid exchange operation, the new chemical is supplied only to the second tank and the third tank, excluding the first tank.
